(19) United States
(12) Patent Application Publication
(10) Pub. No.: US 2025/0320112 A1
(43) Pub. Date: Oct. 16, 2025

(54) MEMS DEVICE

(71) Applicant: Robert Bosch GmbH, Stuttgart (DE)

(72) Inventors: Anton Melnikov, Dresden (DE); Alexander Sorger, Dresden (DE); Andreas Winden, Reutlingen (DE); Jens Schindele, Kirchentellinsfurt (DE); Maximilian Sommer, Dresden (DE); Peter Engelhart, St. Johann (DE)

(21) Appl. No.: 19/089,686

(22) Filed: Mar. 25, 2025

(30) Foreign Application Priority Data
Apr. 11, 2024 (DE) 10 2024 203 334.0

(51) Int. Cl. B81B 7/00

(52) U.S. Cl. CPC B81B 7/0016; B81B 2201/0257; B81B 2201/036; B81B 2203/0145; B81B 2203/04; B81B 2207/11

(57) ABSTRACT

A MEMS device. The MEMS device includes at least one movably mounted element, which performs a useful movement along a useful direction relative to a further element of the MEMS device. The movable element is for interaction with a fluid, such as a gas or a liquid. The movable element includes first and second portions. The further includes further first and second portions. The first portion has a first gap distance from the further first portion in a disturbance direction of the movable element. The second portion has a second gap distance from the further second portion in the disturbance direction of the movable element. A movement of the movably mounted element along the disturbance direction is caused by an external load, such as an external impact. The first gap distance is smaller than the second gap distance. The first portion and the further first portion form a contact region between the movable element and the further element.

### BACKGROUND INFORMATION

The related art includes certain MEMS loudspeakers, which are usually designed as planar structures, having an oscillating membrane that allows displacement or compression of fluid vertically to the membrane plane. Some concepts in the related art offer a plurality of laterally or horizontally movable elements that can expand in the vertical direction instead of a single vertically oscillating membrane.

PCT Patent Application WO 2017/215809 A1 describes a micro-electromechanical microphone comprising a substrate plate and a piezoelectric membrane arranged above the substrate plate. A method for producing such a micro-electromechanical microphone is also described.

Germany Patent Application No. DE 20 2022 100 038 U1 describes a MEMS sound transducer for generating and/or detecting sound waves, in particular in the audible wavelength spectrum, having a membrane support, a membrane that is connected to the membrane support in its edge region and can oscillate relative to the membrane support along a stroke axis, and a MEMS unit that comprises at least one transducer structure that can be deflected along the stroke axis, the transducer structure being connected to the membrane and comprising at least one piezoelectric layer.

A disadvantage is that shock loads or external fluidic pressure loads can cause individual electronic elements to come into unintentional contact, which can lead to damages, particle generation or pull-in.

An object of the present invention is therefore to provide a MEMS device that comprises the most compact design possible and which functions reliably even under external loads, such as external impacts.

### SUMMARY

The present invention relates to a MEMS device including at least one movably mounted element that performs a useful movement along a useful direction relative to a further element of the MEMS device, the movable element being provided for interaction with a fluid, such as a gas or a liquid. According to an example embodiment of the present invention, the movable element comprising a first portion and a second portion, the further element comprising a further first portion and a further second portion, the first portion of the movable element comprising a first gap distance from the further first portion of the further element in a disturbance direction of the movable element, the second portion of the movable element comprising a second gap distance from the further second portion of the further element in the disturbance direction of the movable element, a movement of the movably mounted element along the disturbance direction being caused by a load, such as an external impact, the first gap distance being smaller than the second gap distance, the first portion and the further first portion forming a contact region between the movable element and the further element in that, upon a deflection along the disturbance direction in a first contact position, the first portion of the movable element comes into contact with the further first portion of the further element, the second gap distance forming a protection region between the movable element and the further element, within which contact between the movable element and the further element is avoided even during contact in the contact region.

The MEMS (micro-electromechanical systems) device can be any microelectronic device, such as a loudspeaker, a microphone, or a pump for pumping a fluid, such as a gas or liquid.

Micro-electromechanical devices, i.e., MEMS components, can be multi-layered structures. Such MEMS components can be obtained, for example, by processing semiconductor material at the wafer level, which can also involve combining a plurality of wafers and/or depositing layers at wafer levels. Exemplary embodiments of the present invention described herein may refer to layer stacks having a plurality of layers. However, layers described in this connection may not necessarily be a single layer, but in exemplary embodiments can easily comprise two, three or more layers and be understood as a layer composite. Thus, layers from whose material a movable element is formed can be formed in multiple layers, as can layers between which a movable element is arranged, which can, for example, be designed as at least part of a wafer and can comprise a plurality of material layers, for example for implementing physical, chemical and/or electrical functions. Some of the exemplary embodiments described herein are described in connection with a loudspeaker configuration or a loudspeaker function of a corresponding MEMS component. It is understood that these embodiments, with the exception of the alternative or additional function of a sensory evaluation of the MEMS component or the movement or position of movable elements thereof, are transferable to a microphone configuration or microphone function of the MEMS component, so that such microphones represent further exemplary embodiments of the present invention without limitations. Furthermore, other areas of application of MEMS are also within the scope of the exemplary embodiments described herein, such as micropumps, ultrasonic transducers or other MEMS-based applications related to the movement of fluid. For example, exemplary embodiments can relate to a movement of actuators that can, among other things, interact with a fluid. Exemplary embodiments can also relate to an application of electrostatic forces for a deflection of a movable element. However, the described exemplary embodiments can also be easily implemented using other drive principles, such as electromagnetic force generation or sensing. The deflectable elements can be, for example, electrostatic, piezoelectric and/or thermomechanical electrodes that provide deformation based on an applied potential.

The load can be, for example, an external load caused by an external impact. However, the load can also be caused by an internal force, for example an electrostatic force on the movable element, which leads to a so-called “pull.”

The movable element can perform a movement along a useful direction relative to the further element, which can be designed to be rigid or elastic. This useful movement can, for example, be the vibration of a membrane for generating sound waves in a loudspeaker, the vibration of a membrane for receiving sound waves in a microphone or a movement of a mechanical pumping device to pump a fluid.

The useful movement can, for example, be driven by an electromagnetic force, wherein, for example, a permanent magnet, which can be arranged on the movable element, can be driven by an alternating magnetic field of electrodes, which can be attached to the further element.

According to an example embodiment of the present invention, the movable element can also be moved relative to the further element along the disturbance direction, for example caused by an external impact. The movable element can come into contact with the further element within the contact region, so that the contact region serves as a stop. However, the second gap distance is larger than the first gap distance, so that contact of the movable element with the further element is avoided within the protection region for protecting the electronic components and/or electrodes located therein. As a result safe operation even in the event of external impacts is ensured.

An advantage of this MEMS device of the present invention is that the contact region provides an integrated stop function without the need for additional stop elements, in order to prevent the movable element from abutting against the further element. This reduces the number of design elements, lowers the overall mass of the MEMS device and reduces production costs.

Due to the lower overall mass of the movable element, the total harmonic distortion of the useful movement can be reduced. In a MEMS device designed as a loudspeaker, the lower mass of the movable element can also improve the acoustic performance of the loudspeaker.

Advantageously, the MEMS device can be a loudspeaker, a microphone or a pump for pumping fluid.

As a result, the basic principle of the present MEMS device of the present invention can be used for various micro-electromechanical systems, such as loudspeakers, microphones and pumps.

Advantageously, according to an example embodiment of the present invention, the further second portion of the further element and/or the second portion of the movable element can contain electronic elements that are protected from contact and/or damages.

The protected electronic elements in the protection region can be, for example, electronic components, microchips and/or electrodes. Within the protection region, contact between the movable element and the further element is prevented, so that damages caused by mechanical shocks or short circuits are avoided.

Advantageously, according to an example embodiment of the present invention, the direction of movement of the movable element relative to the further element can comprise a useful direction during normal functioning of the MEMS device and an unwanted disturbance direction, which occurs, for example, during an external impact, it being possible for the disturbance direction to preferably be aligned substantially perpendicular to the useful direction, preferably by means of corresponding guide means.

Due to the substantially perpendicular alignment of the useful direction to the disturbance direction, safe functioning during normal operation is ensured, wherein in the event of a disturbance, such as an external impact, the contact region acts as a stop, thus protecting components within the protection region from damages.

Advantageously, according to an example embodiment of the present invention, the movable element and/or the further element can be arranged on a substrate, it being possible for the movable element and/or the further element and/or the substrate to be designed as a layer stack.

Due to the production of the MEMS device with a layer stack, the production method can be automated by first applying a substrate layer using a corresponding device and subsequently attaching the movable element and/or the further element thereto. The substrate layer can advantageously be non-conductive, so that a cuboidal elevation of the further element is preferably electrically insulated from electrodes, which can be arranged, for example, as strip-shaped electrodes on a lower surface of a plate-shaped support of the further element. As a result, a short circuit, particularly in high humidity conditions, can be prevented.

Advantageously, according to an example embodiment of the present invention, the movable element and/or the further element can be designed to be elastic, so that in the contact position the movable element exerts a compressive force on the further element, so that this leads to an elastic deformation of the movable element and/or the further element.

The difference between the second gap distance and the first gap distance is selected to be large enough to prevent physical contact in the protection region even in the event of elastic deformation of the movable element and/or the further element in the event of an external impact. The elastic deformation of the movable element and/or the further element in the event of an external load, such as an external impact, results in cushioning and, consequently, the transmission of lower forces within the contact region compared to a rigid collision between the movable element and the further element.

Advantageously, according to an example embodiment of the present invention, the first portion of the movable element and/or the further first portion of the further element can comprise an elevation that serves as a stop in the contact position, it being possible for the elevation to preferably comprise the shape of a rectangle or the shape of a hemisphere.

Due to this elevation within the contact region, a punctiform and defined stop is ensured. The elevation can be formed integrally as a component of the movable element and/or the further element.

Advantageously, according to an example embodiment of the present invention, the movement of the movable element relative to the further element can be limited not only by the first contact position but also in an opposite direction in a second contact position, a third gap distance forming a defined second contact region between the movable element and the further element within which, in the second contact position, the movable element comes into contact with the further element, a fourth gap distance forming a defined second protection region between the movable element and the further element, within which contact between the movable element and the further element is also avoided in the second contact position, it being possible for the third gap distance to be smaller than the fourth gap distance.

As a result, the movement of the movable element along the disturbance direction in the second contact position, also in the opposite direction, is limited. Electronic components and/or electrodes that are to be protected from damage can also be arranged within the second protection region.

Advantageously, according to an example embodiment of the present invention, the movable element can comprise at least one electrically conductive region, it being possible for the further element to comprise at least one electrode, it being possible for the movable element to be excited to oscillate along a useful direction by applying a voltage to the electrode, the protection region defined by the second gap distance being selected so that the electrodes in the protection region are protected from contact with the movable element.

As a result, the movable element is driven by an electromagnetic force by applying an alternating voltage to the electrodes, thus preventing a short circuit even in the event of an external impact, since the strip-shaped electrodes are arranged within the defined protection region.

Advantageously, according to an example embodiment of the present invention, the movable element can comprise an I-, T- or double-T-shaped support, it being possible for the further element to comprise at least one electrode arranged within the protection region defined by the second gap distance, in order to prevent contact between the electrode and the I-, T- or double-T-shaped support.

In an I-or double-T-shaped support, an upper T-shaped portion of the support can be connected to the first contact region for limiting the movement of the movable element along the disturbance direction in an upper direction and a lower T-shaped portion of the support can be connected to the second contact region in the opposite direction.

Advantageously, according to an example embodiment of the present invention, the movable element can be designed in the form of a T-shaped support, it being possible for the movable element to comprise a recess in an edge region, it being possible for the further element to comprise an elevation, preferably in the shape of a cuboid. The elevation of the further element can be received in the recess of the movable element, it being possible for the elevation to comprise a distance from the recess, so that contact is avoided during a movement along the useful direction, it being possible for the elevation of the further element to abut against a wall of the recess during a movement along the disturbance direction, for example due to an external impact, and in this contact position within the first protection region defined by the second gap distance, it being possible to prevent contact between the movable element and the further element and thus in particular damage to electrodes and/or electronic components within the first protection region being prevented.

Due to this particularly advantageous embodiment of the present invention, the movable element can be driven by applying an alternating voltage to the strip-shaped electrodes. The elevation of the further element is received in the recess of the movable element at a distance so that, in the event of an external impact, the elevation abuts against a wall within the recess as a stop, wherein contact between the movable element and the lower surface of the additional element, designed in the form of an elongated plate, is prevented, thus forming the protection region.

This example embodiment of the present invention allows for a compact design with high mechanical performance.

Advantageously, according to an example embodiment of the present invention, at least two strip-shaped electrodes can be attached to a lower surface of the further element, preferably designed in the form of an elongated plate, it being possible for the cuboidal elevation to be connected to the lower surface of the elongated plate by means of a preferably non-conductive substrate layer.

Due to the use of a non-conductive substrate layer to connect the cuboidal elevation to the elongated plate, the production process can be automated by first automatically applying a substrate layer and then arranging the elevation thereon.

Advantageously, according to an example embodiment of the present invention, the elevation and/or the substrate layer can be arranged between the at least two strip-shaped electrodes.

The two strip-shaped electrodes are thereby separated by the insulating substrate layer, in order to prevent a possible short circuit between the electrodes, for example, in the case of higher humidity.

Advantageously, according to an example embodiment of the present inventon, a first substrate layer at one end of the elevation and a second substrate layer at an opposite end of the elevation can connect the lower surface of the further element to the cuboidal elevation, it being possible for the at least two electrodes to be arranged between the two substrate layers.

Due to this arrangement of the two electrodes between the two substrate layers, a mechanically stable mounting of the elevation on the lower surface of the plate is allowed for.

Advantageously, according to an example embodiment of the present invention, a first substrate layer at one end of the elevation and a second substrate layer at an opposite end of the elevation can connect the lower surface of the further element to the cuboidal elevation, it being possible for only one electrode to be arranged between the two substrate layers, it being possible for the at least one remaining electrode to be arranged next to one of the substrate layers.

This arrangement has the advantage that the two electrodes are separated by a substrate layer, so that the probability of a short circuit is reduced.

### BRIEF DESCRIPTION OF THE DRAWINGS

The present invention is explained with reference to the figures.

FIG. 1 is a schematic representation of a MEMS device, according to an example embodiment of the present invention.

FIG. 2 is a schematic representation of a further example embodiment of the MEMS device of the present invention.

FIG. 3 is a schematic representation of a further example embodiment of the MEMS device of the present invention having a second contact region.

FIG. 4 shows the MEMS device from FIG. 3 in a first contact position deflected upwards along the disturbance direction, according to an example embodiment of the present invention.

FIG. 5 shows the MEMS device from FIG. 3 in a second contact position deflected downwards along the disturbance direction, according to an example embodiment of the present invention.

FIG. 6 is a schematic representation of a further example embodiment of the MEMS device with an elastic element, according to the present invention.

FIG. 7 is a schematic representation of further example embodiments of the MEMS device with stops, according to the present invention.

FIG. 8 shows the embodiments from FIG. 7 in a deflected contact position, according to the present invention.

FIG. 9 is a schematic representation of further embodiments of the MEMS device with stops on the further element, according to the present invention.

FIG. 10 shows the embodiments from FIG. 9 in a deflected contact position, according to the present invention.

FIG. 11 is a schematic representation of further example embodiments of the MEMS device with two stops, according to the present invention.

FIG. 12 shows further example embodiments with differently shaped elevations, according the present invention.

FIG. 13 shows a further example embodiment of the MEMS device as in FIG. 6 with an elastic element and a second contact region, according to the present invention.

FIG. 14 shows further example embodiments of the MEMS device with two contact regions, according to the present invention.

FIG. 15 is a schematic representation of a further example embodiment of the MEMS device, according to the present invention.

FIG. 16 shows sectional views along the planes AA, BB and CC from FIG. 15.

FIG. 17 is a schematic representation of a further example embodiment of the MEMS device, according to the present invention.

FIG. 18 shows sectional views along the planes AA, BB and CC from FIG. 17,

FIG. 19 is a schematic representation of a further example embodiment of the MEMS device, according to the present invention.

FIG. 20 shows sectional views along the planes AA, BB and CC from FIG. 19.

FIG. 21 is a schematic representation of a further example embodiment of the MEMS device, according to the present invention.

FIG. 22 shows sectional views along the planes AA, BB and CC from FIG. 21.

FIG. 23 is a schematic representation of a further example embodiment of the MEMS device with a plurality of movable elements, according to the present invention.

FIG. 24 is a schematic representation of a further example embodiment of the MEMS device with an additional electrode, according to the present invention.

FIG. 25 is a schematic representation of a further example embodiment of the MEMS device with lateral stops, according to an example embodiment of the present inventon.

### DETAILED DESCRIPTION OF EXAMPLE EMBODIMENTS

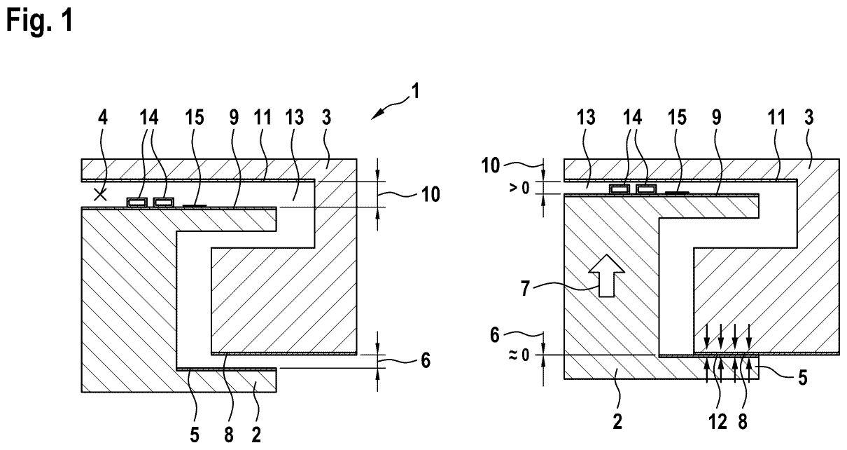

FIG. 1 is a schematic representation of a MEMS device 1 comprising a movably mounted element 2 that performs a useful movement relative to a further element 3 along a useful direction 4, which in the present case points into the plane of the drawing. The useful movement can be an oscillating movement. The MEMS device 1 can be designed, for example, as a loudspeaker, a microphone or a pump for a fluid, such as a gas or a liquid, which is arranged between the movable element 2 and the further element 3. The movable element 2 comprises a first portion 5 with a first gap distance 6 along a disturbance direction 7 from a further first portion 8 of the further element 3. In addition, the movable element 2 comprises a second portion 9 with a second gap distance 10 from a further second portion 11 of the further element 3 along the disturbance direction 7, which can be caused, for example, by an external impact. The first gap distance 6 is smaller than the second gap distance 10. The left-hand representation shows the MEMS device 1 in a non-deflected state. The right-hand representation shows the MEMS device 1 in a deflected state in a first contact position, the first portion 5 of the movable element 2 coming into contact with the further first portion 8 of the further element 3 thereby forming a contact region 12 between the movable element 2 and the further element 3. Between the second portion 9 of the movable element 2 and the further second portion 11 of the further element 3, a defined protection region 13 is formed by the second gap distance 10, within which contact is avoided. Within the protection region 13, electronic components 14 and electrodes 15 are arranged, which are to be protected from damage by the external impact.

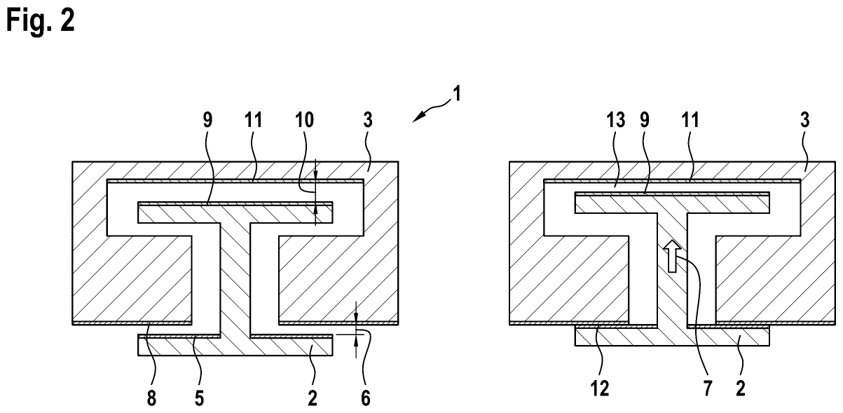

FIG. 2 is a schematic representation of a further embodiment of the MEMS device 1, the movable element 2 being designed as a double-T-shaped support. The left-hand representation shows the MEMS device 1 in a non-deflected state and the right-hand representation shows the MEMS device 1 in a deflected state, the first portion 5 of the movable element 2 coming into contact with the further first portion 8 of the further element 3 and thereby forming the contact region 12, the protection region 13 being formed between the second portion 9 and the further second portion 11.

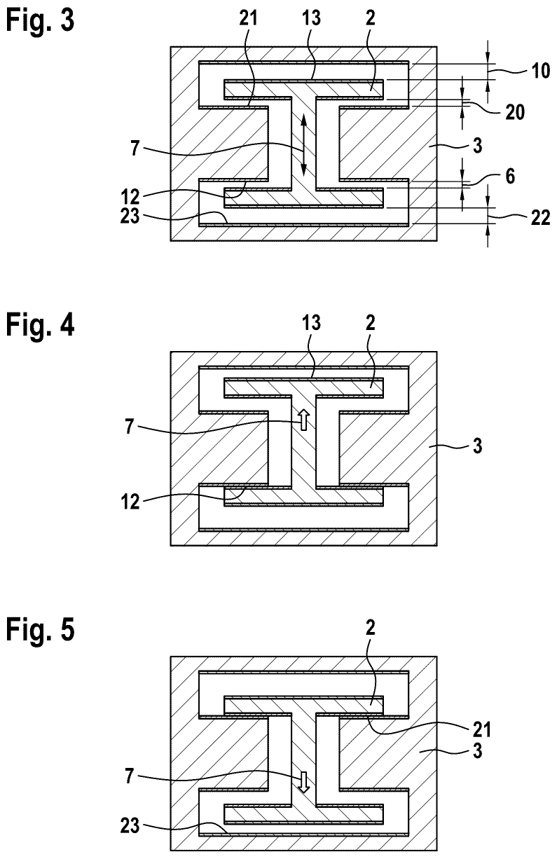

FIG. 3 is a schematic representation of a further embodiment of the MEMS device 1, the movable element 2 being designed as a double-T-shaped support. The movement of the movable element 2 along the disturbance direction 7 is not only limited upwards, but is also limited downwards. A third gap distance 20 forms a second contact region 21, a fourth gap distance 22 forming a second protection region 23.

FIG. 4 shows the MEMS device 1 from FIG. 3 in a first contact position deflected upwards along the disturbance direction 7, so that within the first contact region 12 the movable element 2 comes into contact with the further element 3, contact being avoided within the first protection region 13.

FIG. 5 shows the MEMS device 1 from FIG. 3 in a second contact position deflected downwards along the disturbance direction 7, so that within the second contact region 21, the movable element 2 comes into contact with the further element 3, contact being avoided within the second protection region 23.

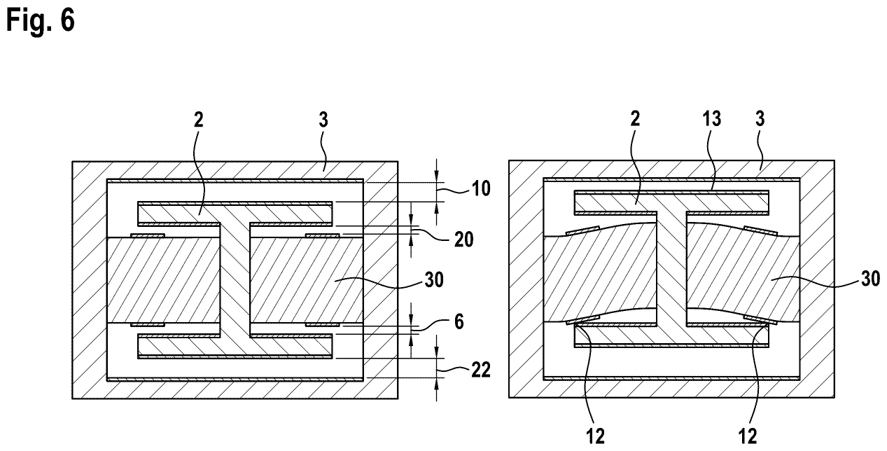

FIG. 6 is a schematic representation of a further embodiment of the MEMS device 1, the movable element 2 being designed as a double-T-shaped support. The further element 3 comprises a frame and an elastic element 30. In the left-hand representation, the MEMS device 1 is shown in a non-deflected position. In the right-hand representation, the MEMS device 1 is shown in a deflected position, the movable element 2 coming into punctiform contact with the further element 3 within the first contact region 12 and the elastic element 30 of the further element 3 being deformed upwards. The elasticity of the elastic element 30 and the second gap distance 10 are selected so that the elastic deformation of the elastic element 30 caused by the external impact does not lead to contact within the protection region 13, so that the electronic elements and electrodes arranged therein are protected. The third gap distance 20 and the fourth gap distance 22 are also selected so that the movement along the disturbance direction 7 is also limited in the opposite direction and a second protection region is formed.

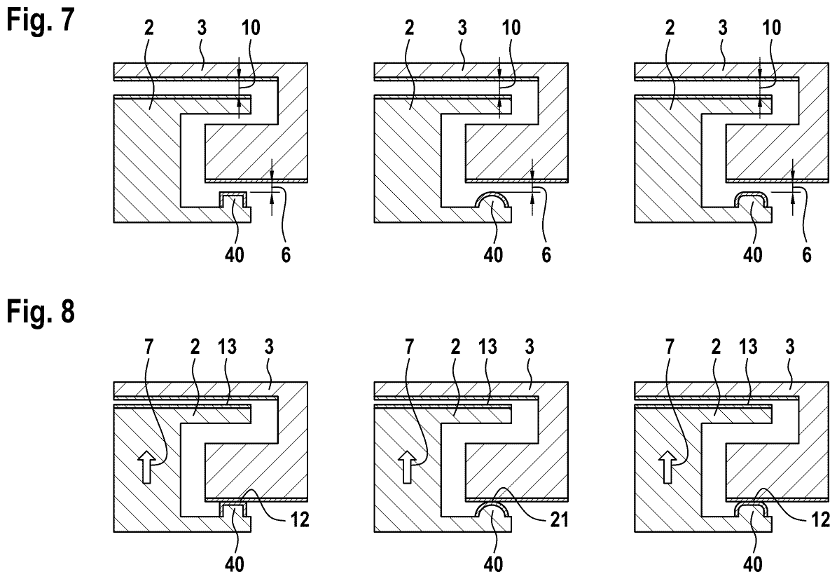

FIG. 7 is a schematic representation of further embodiments of the MEMS device 1, in the left-hand representation the movable element 2 within the first contact region 12 comprising an elevation 40 as a stop in the contact position in the form of a cuboid, in the middle representation the movable element 2 within the first contact region 12 comprising an elevation 40 as a stop in the form of a hemisphere, in the right-hand representation the movable element 2 within the first contact region 12 comprising an elevation 40 as a stop in the form of a rounded cuboid.

FIG. 8 shows the embodiments from FIG. 7 in a deflected contact position, so that the elevation 40 allows for a punctiform, defined contact as a stop.

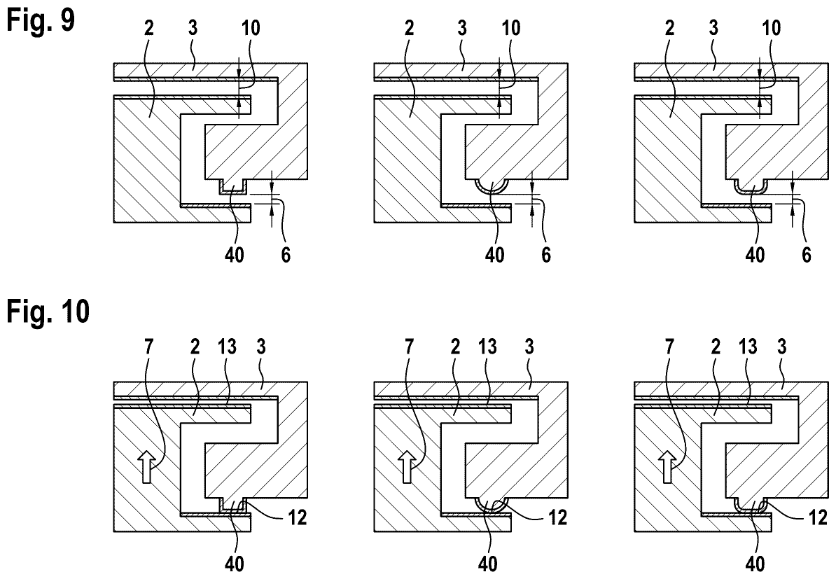

FIG. 9 is a schematic representation of further embodiments of the MEMS device 1, in the left-hand representation the further element 3 within the first contact region 12 comprising an elevation 40 as a stop in the contact position in the form of a cuboid, in the middle representation the further element 3 within the first contact region 12 comprising an elevation 40 as a stop in the form of a hemisphere, in the right-hand representation the further element 3 within the first contact region 12 comprising an elevation 40 as a stop in the form of a rounded cuboid.

FIG. 10 shows the embodiments from FIG. 9 in a deflected contact position, so that the elevation 40 allows for a punctiform, defined contact as a stop.

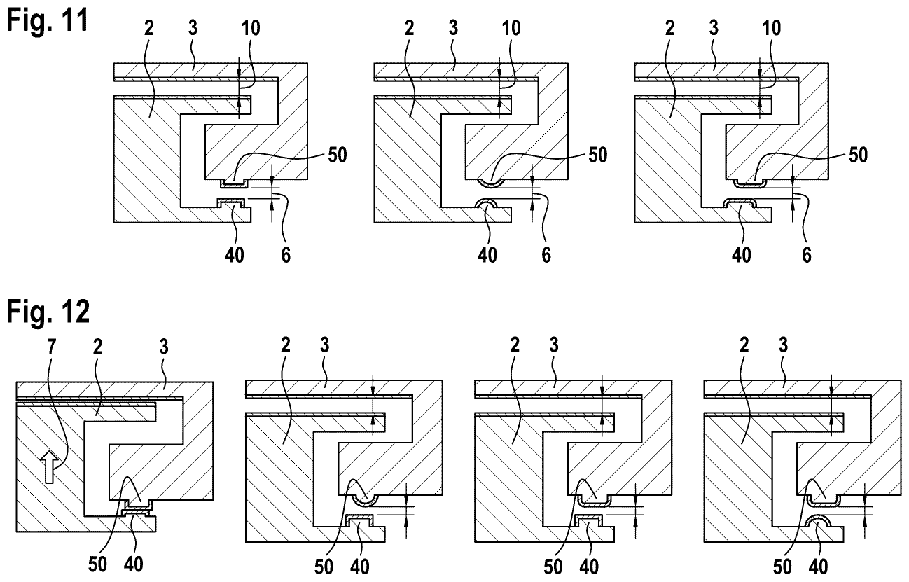

FIG. 11 is a schematic representation of further embodiments of the MEMS device 1, in the left-hand representation the movable element 2 comprising a first elevation 40 in the form of a cuboid and the further element 3 within the first contact region 12 comprising a second elevation 50 as a stop in the contact position in the form of a cuboid, in the left-hand [sic]¹ representation the movable element 2 comprising a first elevation 40 in the form of a hemisphere and the further element 3 within the first contact region 12 comprising a second elevation 50 as a stop in the contact position in the form of a hemisphere, and in the left-hand [sic]² representation the movable element 2 comprising a first elevation 40 in the form of a rounded cuboid and the further element 3 within the first contact region 12 comprising a second elevation 50 as a stop in the contact position in the form of a rounded cuboid. ¹ [Translator's note: This should probably read “center” or “middle”, see FIG. 11.]² [Translator's note: This should probably read “right-hand”, see FIG. 11.]

FIG. 12 shows further embodiments with differently shaped elevations 40 and 50, so that the first elevation 40 and the second elevation 50 allow for a punctiform, defined contact as a stop.

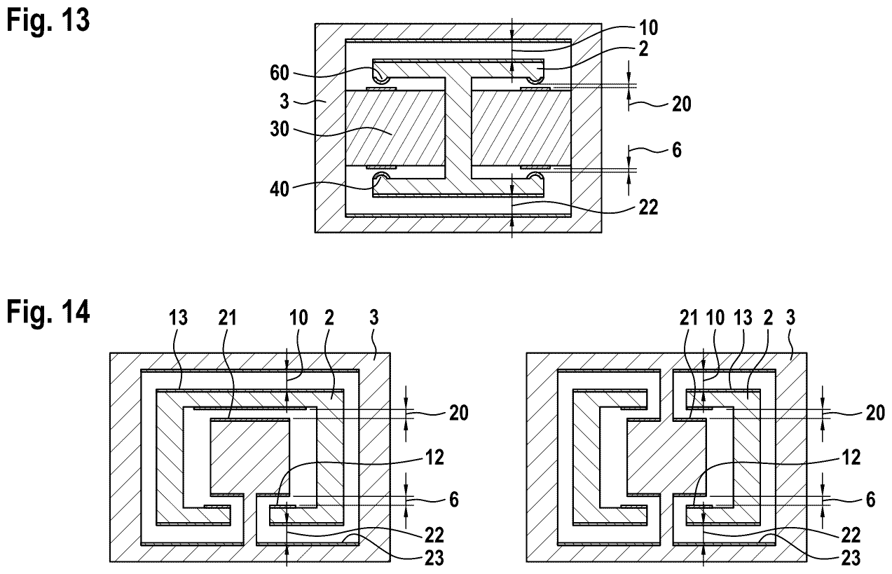

FIG. 13 shows a further embodiment of the MEMS device 1, as in FIG. 6, with an elastic element 30, the movable element 2, however, comprising an elevation 40 in the form of a hemisphere within the first contact region 12 and a further elevation 60 in the form of a hemisphere as a punctiform stop within the second contact region 21. The elevations 40 and 60 can be formed integrally with the movable element 2.

FIG. 14 shows further embodiments of the MEMS device 1, the movable element 2 in the left-hand representation being shaped in the form of a frame with a recess, the movable element 2 in the right-hand representation consisting of two parts that can be connected by connecting means (not shown). The movement along the disturbance direction 7 is limited upwards by the first contact region 12 and downwards by the second contact region 21.

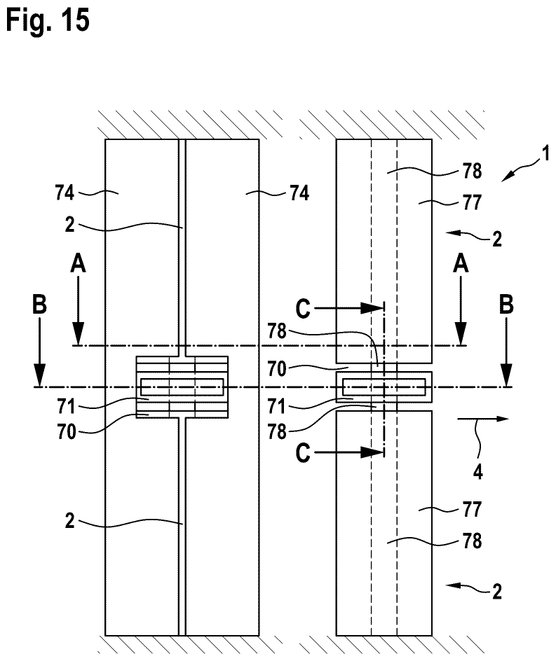

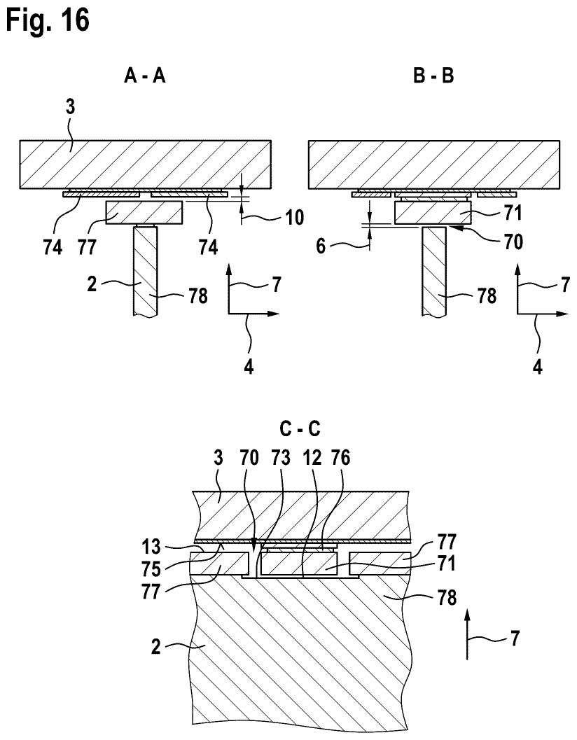

FIG. 15 is a schematic representation of a further embodiment of the MEMS device 1 with sectional views along the planes AA, BB and CC in FIG. 16. The left-hand representation in FIG. 15 shows a schematic representation of the electrodes 74 on the further element 3, the right-hand representation in FIG. 15 being a schematic representation of the movable element 2 in the form of a T-shaped support having a transverse web 77 and a central web 78.

In the example shown, the movable element 2 is designed in the form of a T-shaped support, the movable element 2 comprising a recess 70 in an edge region, i.e. at least in the transverse web 77 and preferably in the central web 78.

The further element 3 is designed, for example, by a wall or in the form of an elongated plate and comprises an elevation 71 that protrudes from the further element 3 in the direction of the movable element 2. The elevation 71 can be designed, for example, in the shape of a cuboid. The elevation 71 of the further element 3 protrudes into the recess 70 of the movable element 2 and is at least partially received in the recess 70. During a movement of the movable element 2 along the useful direction 4, the elevation 71 comprises a distance 72 from the movable element 2, so that contact is avoided. During a movement along the disturbance direction 7, i.e. in the direction of the further element 3, for example due to an external impact, the elevation 71 can abut against a wall 73 of the recess 70. In this contact position, contact between the movable element 2 and the further element 3 is prevented within the first protection region 13 defined by the second gap distance 10 and thus damage to electrodes 74 within the first protection region 13 is prevented.

The two electrodes 74 are attached to a lower surface 75 of the further element 3 and are used to drive the movable element 2 by applying an alternating voltage. The elevation 71 is connected to the lower surface 75 of the further element 3 by means of a non-conductive substrate layer 76 and is arranged between the electrodes 74.

In the embodiment shown in FIG. 15, the movable element 2 is fastened on opposite sides, in the figure at the top and bottom, to an element, in particular a wall, of the device. As a result, the movable element 2 can bend along the useful direction 4 substantially in the central region. Depending on the selected design, the movable element 2 can also be connected to the device on only one side.

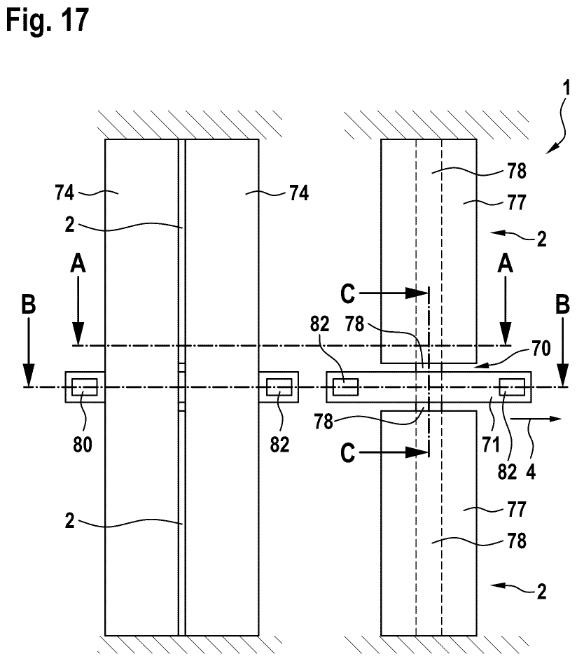

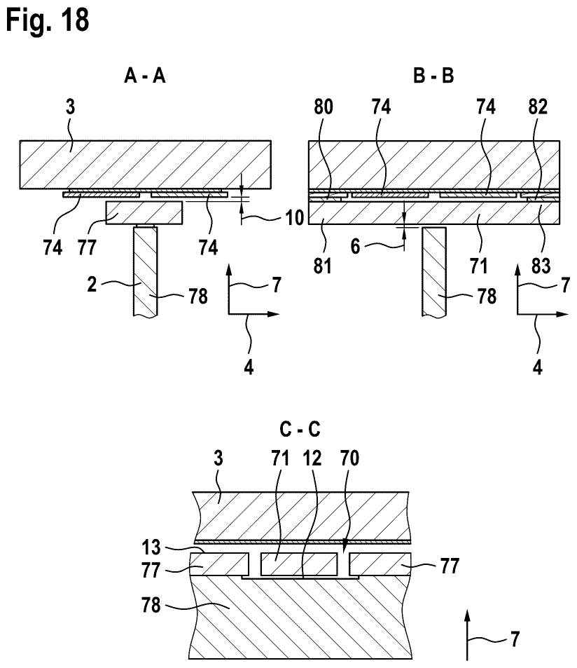

FIG. 17 is a schematic representation of a further embodiment of the MEMS device 1 with sectional views along the planes AA, BB and CC in FIG. 18, which is designed similarly to the embodiment from FIG. 15 and FIG. 16, the difference being that a first substrate layer 80 at one end 81 of the elevation 71 and a second substrate layer 82 at an opposite end 83 of the elevation 71 connects the lower surface 75 of the further element 3 to the cuboidal elevation 71, the two electrodes 74 being arranged between the two substrate layers 80, 82. Thus, the elevation 71 forms a kind of bracket or plate that extends transversely to the longitudinal extent of the electrodes 74 over both electrodes 74. Thus, the elevation 71 can represent an elastic stop for the movable element 2.

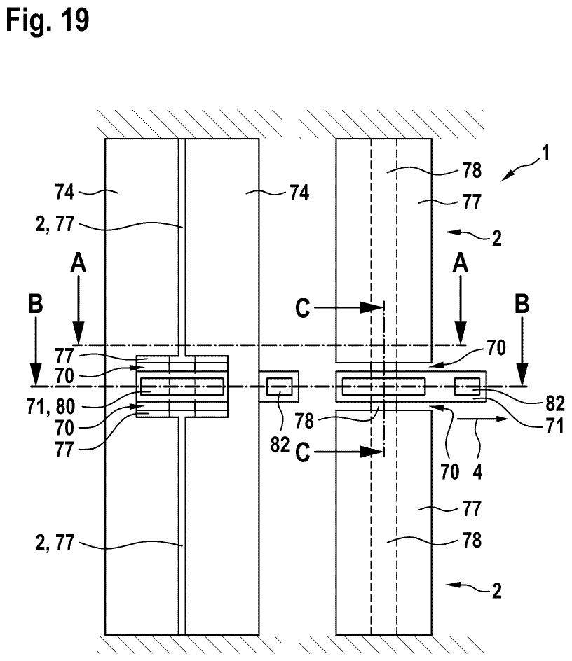

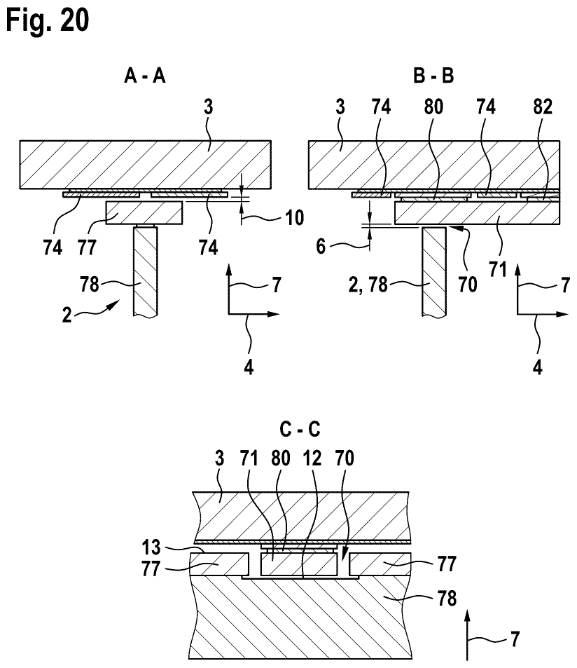

FIG. 19 is a schematic representation of a further embodiment of the MEMS device 1 with sectional views along the planes AA, BB and CC in FIG. 20, which is designed similarly to the embodiment from FIG. 15 and FIG. 16, the difference being that a first substrate layer 80 at one end 81 of the elevation 71 and a second substrate layer 82 at an opposite end 83 of the elevation 71 connects the lower surface 75 of the further element 3 to the cuboidal elevation 71, only one electrode 74 being arranged between the two substrate layers 80 and 82, the at least one remaining electrode 74 being arranged next to one of the substrate layers 80 and 82. Thus, the elevation 71 forms a kind of bracket or plate that extends transversely to the longitudinal extent of an electrode 74.

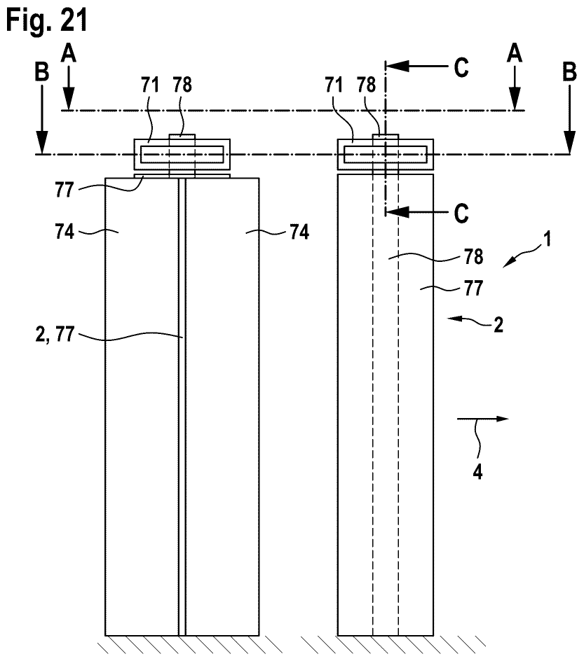

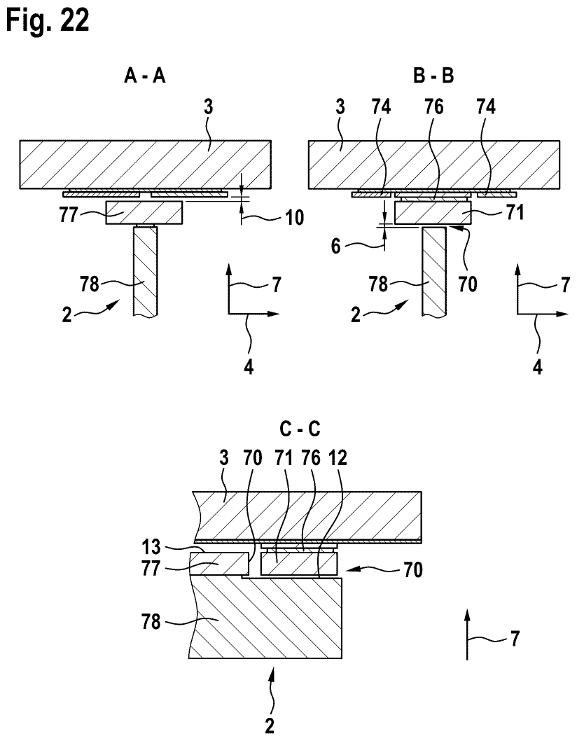

FIG. 21 is a schematic representation of a further embodiment of the MEMS device 1 with sectional views along the planes AA, BB and CC in FIG. 22, which is designed similarly to the embodiment from FIG. 15 and FIG. 16, the difference being that the substrate layer 76 connects the elevation 71 directly to the lower surface 75 of the further element 3 and the recess 70 for receiving the elevation 71 is laterally open, so that, for example, electromagnetic potential can be measured laterally by means of a detector, in order to detect the movement of the movable element 2 along the useful direction 4 and along the disturbance direction 7. In the embodiment shown, the movable element 2 is fastened only on one side, in the figure at the bottom, to an element, in particular a wall, of the device. As a result, the movable element 2 with the free end can bend more strongly along the useful direction 4.

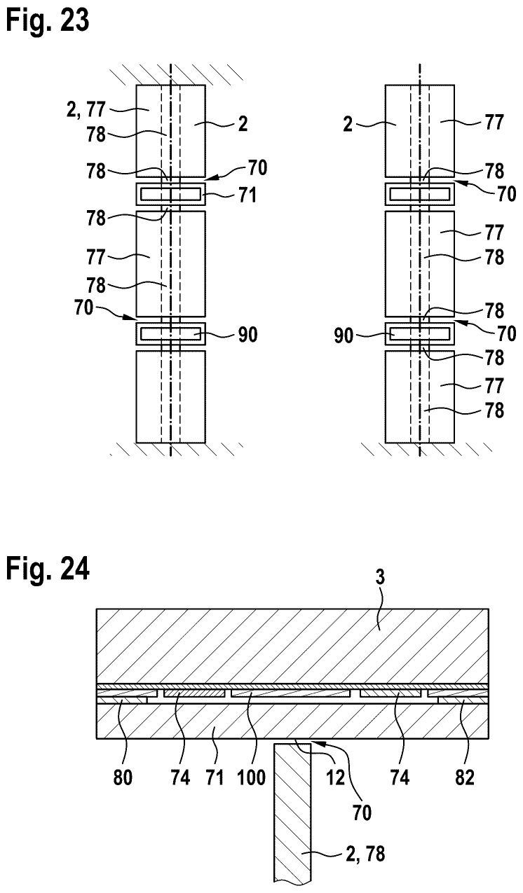

FIG. 23 is a schematic representation of a further embodiment of the MEMS device 1, which is designed similarly to the embodiment from FIG. 15 and FIG. 16, the left-hand representation showing a MEMS device 1 that is connected to the device from both sides, in the figure at the top and bottom, i.e. is clamped, the movable element 2 comprising the first recess 70 with the first elevation 71 of the further element 3 arranged therein and a second recess 90 with a second elevation 91 of the further element 3 arranged therein, it being possible for the movable element 2 with the two recesses 70 and 90 to perform a movement along the useful direction 4 and the disturbance direction 7. The right-hand representation shows a similar MEMS device 1, which, however, is connected to the device only on one side, i.e. is firmly clamped.

FIG. 24 is a schematic representation of a further embodiment of the MEMS device 1, which is designed similarly to the embodiment from FIG. 17 and FIG. 18, the difference being that an additional electrode 100 is arranged between the two substrate layers 80 and 82 in addition to the two electrodes 74.

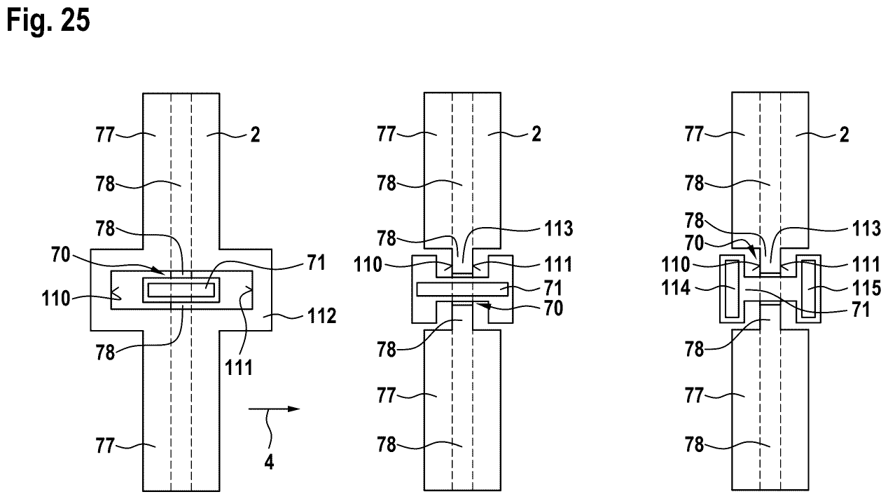

FIG. 25 is a schematic representation of a further embodiment of the MEMS device 1, which is designed similarly to the embodiment from FIG. 15 and FIG. 16, the difference being that the movement of the elevation 71 of the further element 3 along the useful direction 4 is also limited in the lateral direction by a first lateral stop surface 110 and a second lateral stop surface 111. In the middle representation, the two lateral stop surfaces 110 and 111 are arranged on an inner side of a frame 112 of the movable element 2, in the right-hand representation the two lateral stop surfaces 110 and 111 being arranged on the outer sides of a web 113 of the movable element 2. In the right-hand representation, in comparison to the middle representation, a first substrate layer 114 is arranged at one end of the elevation 71 and a second substrate layer 115 is arranged at another end of the elevation 71, the lateral stop surfaces 110 and 111 being arranged on the outer sides of the web 113.

1-15. (canceled)

16. A micro-electromechanical system (MEMS) device, comprising:
at least one movably mounted element which performs a useful movement along a useful direction relative to a further element of the MEMS device, the movably mounted element being configured to interact with a fluid, the movably mounted element including a first portion and a second portion, the further element including a further first portion and a further second portion, the first portion of the movably mounted element having a first gap distance from the further first portion of the further element in a disturbance direction of the movably mounted element, the second portion of the movably mounted element having a second gap distance from the further second portion of the further element in the disturbance direction of the movably mounted element, a movement of the movably mounted element along the disturbance direction being caused by a load, the first gap distance being smaller than the second gap distance, the first portion and the further first portion forming a contact region between the movably mounted element and the further element, wherein upon deflection along the disturbance direction in a first contact position, the first portion of the movably mounted element comes into contact with the further first portion of the further element, the second gap distance forming a protection region between the movably mounted element and the further element within which contact between the movably mounted element and the further element is avoided even during contact in the contact region.

17. The MEMS device according to claim 16, wherein the MEMS device is a loudspeaker or a microphone or a pump for pumping fluid.

18. The MEMS device according to claim 16, wherein the further second portion of the further element and/or the second portion of the movably mounted element contain electronic elements that are protected from contact and/or from damage.

19. The MEMS device according to claim 16, wherein a direction of movement of the movable element relative to the further element includes a useful direction during normal functioning of the MEMS device and an unwanted disturbance direction that occurs during an external impact, the disturbance direction being aligned substantially perpendicular to the useful direction using a guide element.

20. The MEMS device according to claim 16, wherein the movably mounted element and/or the further element are arranged on a substrate, the movably mounted element and/or the further element and/or the substrate being configured as a layer stack.

21. The MEMS device according to claim 16, wherein the movably mounted element and/or the further element are elastic, so that in a contact position, the movably mounted element exerts a compressive force on the further element leading to an elastic deformation of the movably mounted element and/or the further element.

22. The MEMS device according to claim 16, wherein the first portion of the movable element and/or the further first portion of the further element include an elevation that serves as a stop in a contact position, the elevation including a shape of a rectangle or a shape of a hemisphere.

23. The MEMS device according to claim 16, wherein the movement of the movably mounted element relative to the further element is limited not only by the first contact position but also in an opposite direction in a second contact position, a third gap distance forming a defined second contact region between the movably mounted element and the further element, within which, in the second contact position, the movably mounted element comes into contact with the further element, a fourth gap distance forming a defined second protection region between the movably mounted element and the further element, within which contact between the movably mounted element and the further element is also avoided in the second contact position, the third gap distance being smaller than the fourth gap distance.

24. The MEMS device according to claim 16, wherein the movably mounted element includes at least one electrically conductive region, the further element includes at least one electrode, wherein applying a voltage to the electrode excites the movably mounted element to oscillate along the useful direction, the protection region defined by the second gap distance being selected so that electrodes in the protection region are protected from contact with the movably mounted element.

25. The MEMS device according to claim 16, wherein the movably mounted element includes an I-shaped support or a T-shaped support or a double-T-shaped support, the further element includes at least one electrode arranged within the protection region defined by the second gap distance to prevent contact between the at least one electrode and the I-shaped support or the T-shaped support or the double-T-shaped support.

26. The MEMS device according to claim 16, wherein the movably mounted element is configured in the form of a T-shaped support or I-shaped support, the movably mounted element including a recess in an edge region, the further element including an elevation, the elevation of the further element being received in the recess of the movably mounted element, the elevation including a distance from the movably mounted element, so that contact is avoided during a movement along the useful direction, the elevation of the further element abutting against a wall of the movably mounted element in the recess during a movement along the disturbance direction, and in a contact position within the first protection region defined by the second gap distance, contact between the movably mounted element and the further element is prevented and damage to electrodes and/or electronic components within the first protection region is prevented.

27. The MEMS device according to claim 26, wherein at least two strip-shaped electrodes are attached to a lower surface of the further element, the elevation being connected to the lower surface of the elongated plate by a non-conductive substrate layer.

28. The MEMS device according to claim 26, wherein the elevation is arranged between at least two strip-shaped electrodes.

29. The MEMS device according to claim 28, wherein a first substrate layer at one end of the elevation and a second substrate layer at an opposite end of the elevation connecting a lower surface of the further element to the elevation, the at least two electrodes being arranged between the first and second substrate layers.

30. The MEMS device according to claim 28, wherein a first substrate layer at one end of the elevation and a second substrate layer at an opposite end of the elevation connect a lower surface of the further element to the elevation, only one electrode of the at least two electrodes being arranged between the first and second substrate layers, at least one remaining electrode being arranged next to one of the first and second substrate layers.
